(19) United States
(12) Patent Application Publication
(10) Pub. No.: US 2020/0066626 A1
(43) Pub. Date: Feb. 27, 2020

(54) POCKET STRUCTURES, MATERIALS, AND METHODS FOR INTEGRATED CIRCUIT PACKAGE SUPPORTS

(71) Applicant: Intel Corporation, Santa Clara, CA (US)

(72) Inventors: Jason M. Gamba, Gilbert, AZ (US); David Unruh, Chandler, AZ (US); Adrian Kemal Bayraktaroglu, Chandler, AZ (US); Thomas S. Heaton, Mesa, AZ (US)

(73) Assignee: Intel Corporation, Santa Clara, CA (US)

(21) Appl. No.: 16/107,655

(22) Filed: Aug. 21, 2018

(51) Int. Cl. H01L 23/498; H01L 21/683; H01L 21/48

(52) U.S. Cl. CPC H01L 23/49838; H01L 23/49822; H01L 21/4857; H01L 21/6835; H01L 23/49866

(57) ABSTRACT

Disclosed herein are pocket structures, materials, and methods for integrated circuit (IC) package supports. For example, in some embodiments, an IC package support may include: an interconnect pocket having sidewalls provided by a dielectric material; and a conductive contact at a bottom of the interconnect pocket, wherein the conductive contact includes a first metal material and a second metal material, the first metal material provides a bottom surface of the interconnect pocket and is in contact with the dielectric material, the second metal material has a different composition than the first metal material, and the second metal material is in contact with the dielectric material.

### BACKGROUND

In an integrated circuit (IC) assembly, such as an IC package, one component may be mounted to another component by intervening interconnects (e.g., wirebonds or solder interconnects).

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1 is a side, cross-sectional view of a portion of an integrated circuit (IC) package support including an interconnect pocket, in accordance with various embodiments.

FIGS. 2A-2N illustrate stages in an example process of manufacturing an IC package support including an interconnect pocket, in accordance with various embodiments.

FIGS. 3A-3D illustrate stages in an example process of electrolessly depositing a metal on a temporary bond film (TBF), in accordance with various embodiments.

FIG. 4 is a top view of a wafer and dies that may be included in an IC package along with an IC package support in accordance with any of the embodiments disclosed herein.

FIG. 5 is a side, cross-sectional view of an IC device that may be included in an IC package along with an IC package support in accordance with any of the embodiments disclosed herein.

FIG. 6 is a side, cross-sectional view of an IC package that may include an IC package support in accordance with any of the embodiments disclosed herein.

FIG. 7 is a side, cross-sectional view of an IC device assembly that may include an IC package support in accordance with any of the embodiments disclosed herein.

FIG. 8 is a block diagram of an example electrical device that may include an IC package support in accordance with any of the embodiments disclosed herein.

### DETAILED DESCRIPTION

Disclosed herein are pocket structures, materials, and methods for integrated circuit (IC) package supports. For example, in some embodiments, an IC package support may include: an interconnect pocket having sidewalls provided by a dielectric material; and a conductive contact at a bottom of the interconnect pocket, wherein the conductive contact includes a first metal material and a second metal material, the first metal material provides a bottom surface of the interconnect pocket and is in contact with the dielectric material, the second metal material has a different composition than the first metal material, and the second metal material is in contact with the dielectric material.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The drawings are not necessarily to scale. Although many of the drawings illustrate rectilinear structures with flat walls and right-angle corners, this is simply for ease of illustration, and actual devices made using these techniques will exhibit rounded corners, surface roughness, and other features.

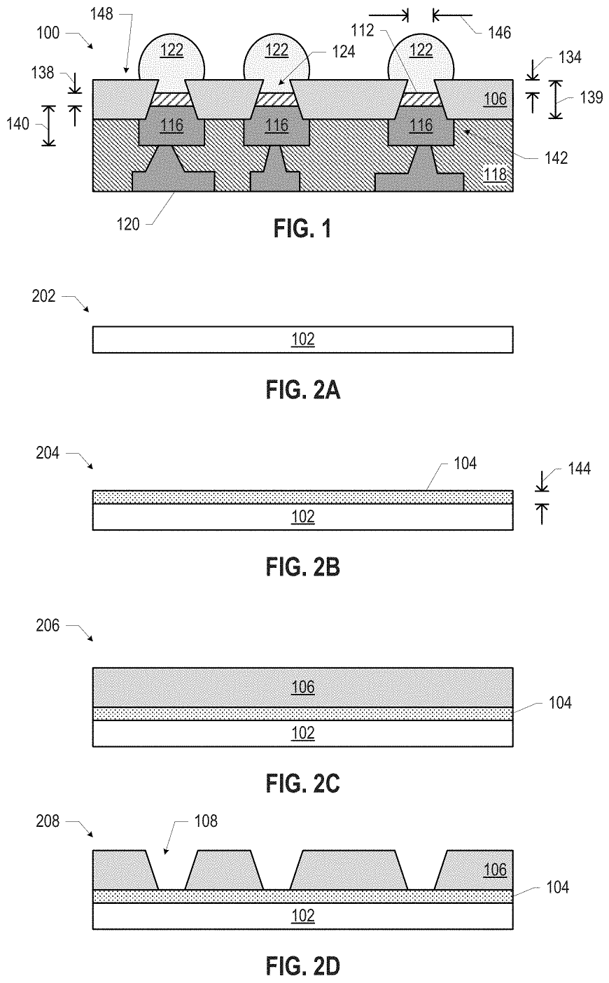

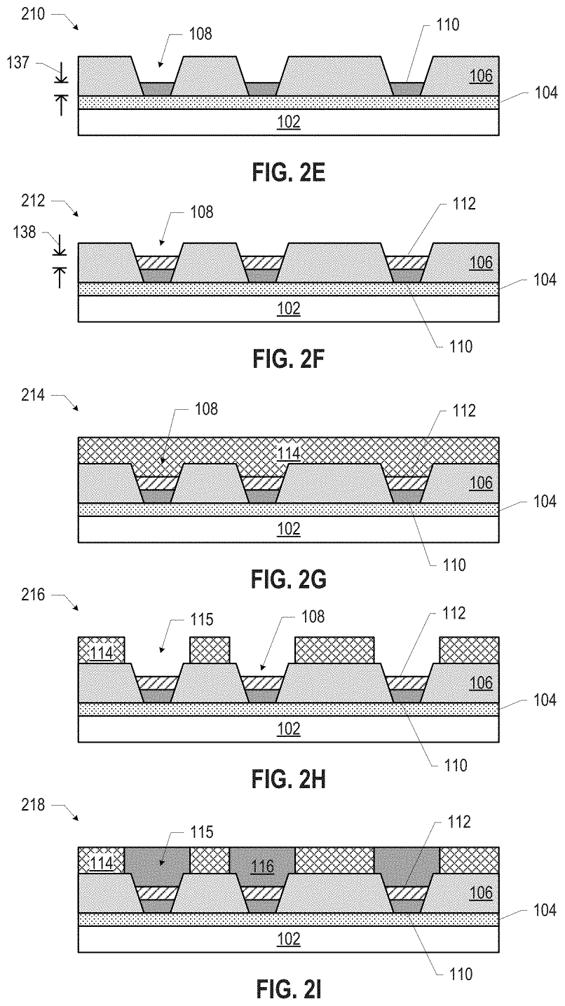

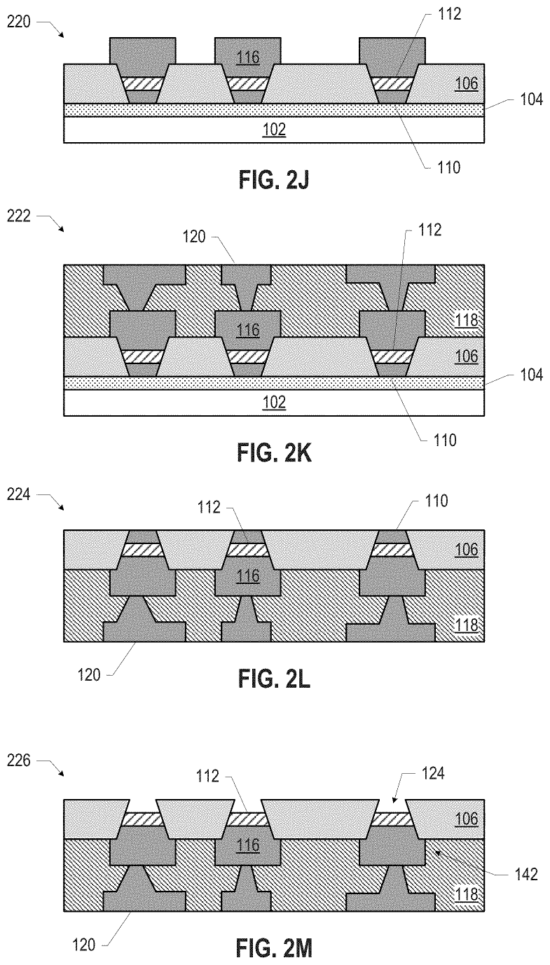

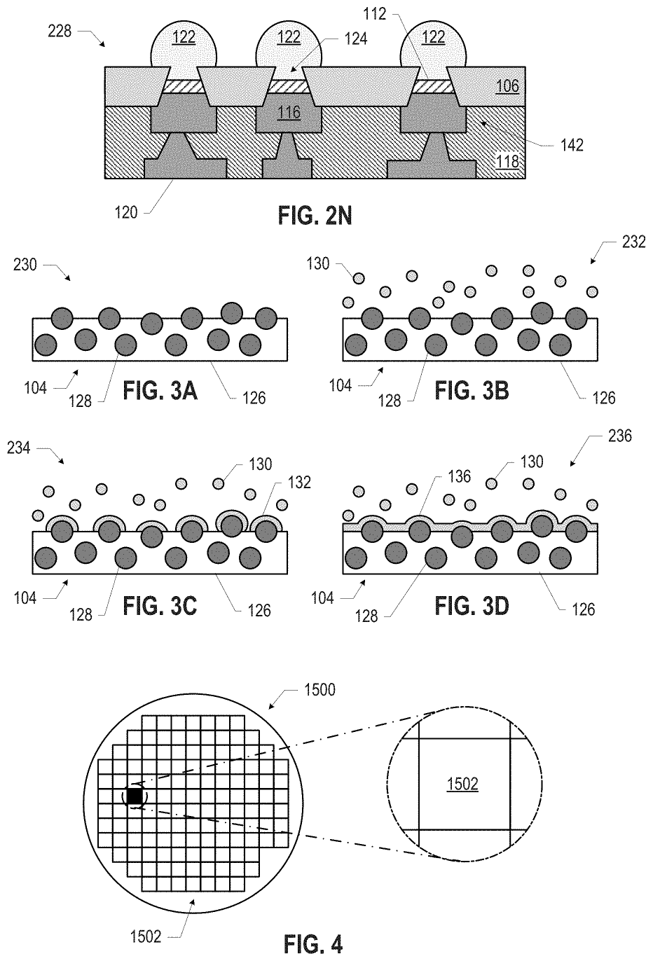

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous. When used to describe a range of dimensions, the phrase “between X and Y” represents a range that includes X and Y. For convenience, the phrase “FIG. 2” may be used to refer to the collection of drawings of FIGS. 2A-2N, and the phrase “FIG. 3” may be used to refer to the collection of drawings of FIGS. 3A-3D. As used herein, an “IC package support” or “package support” may refer to a structure included in an IC package that provides mechanical and/or electrical support to one or more dies or other electrical components (e.g., passive or active components) included in the IC package.

FIG. 1 is a side, cross-sectional view of a portion of an IC package support 100 including multiple interconnect pockets 124 at a face 148 of the IC package support 100. As discussed further below, the IC package support 100 of FIG. 1 (and others of the accompanying figures) may be part of a package substrate (e.g., the package substrate 1652 discussed below with reference to FIG. 6), an interposer (e.g., the interposer 1657 discussed below with reference to FIG. 6), or any other components included in an IC package.

Individual interconnect pockets 124 may have sidewalls provided by a dielectric material 106 and a bottom surface provided by a conductive contact 142. The dielectric material 106 may include a buildup material, such as Ajinomoto buildup film (ABF), or another suitable dielectric. In some embodiments, the interconnect pockets 124 may be the top portion of openings in the dielectric material 106, and these openings may be tapered, narrowing toward the face 148 and widening away from the face 148.

The conductive contact 142 may include a first metal material 112 and a second metal material 116. The first metal material 112 may be a “surface finish” material that may serve as a barrier between the second metal material 116 and the ambient environment during manufacturing (e.g., to mitigate oxidation of the second metal material 116). In some embodiments, the first metal material 112 may include a noble metal (e.g., palladium and/or gold) and/or nickel. In some embodiments, the first metal material 112 may include palladium, gold, and nickel. The second metal material 116 may provide the “bulk” of the conductive contact 142. In some embodiments, the second metal material 116 may include copper. As illustrated in FIG. 1, the first metal material 112 may provide the entire bottom surface of an interconnect pocket 124, and may contact the dielectric material 106 at the sides of each interconnect pocket 124. The second metal material 116 may not be present at the bottom surface of the interconnect pocket 124. This structure for the conductive contacts 142 may be advantageous relative to previous approaches in which the bulk material of a conductive contact (e.g., copper) is exposed close to the sidewalls of an interconnect pocket. In such previous approaches, the exposure of this bulk material to the ambient environment may result in undesirable oxidation that may limit the current flow through the conductive contact and/or may compromise the strength of the joint between the conductive contact and the interconnect (e.g., solder) in the interconnect pocket.

As noted above, the first metal material 112 of the conductive contacts 142 may be exposed at the bottoms of the interconnect pockets 124. Interconnects 122 may be deposited or attached on the exposed portions of the conductive contacts 142, and may be partially disposed in the interconnect pockets 124 while extending out of the interconnect pockets 124. In some embodiments, the interconnects 122 may include solder. In use, the interconnects 122 may couple the IC package support 100 to another component (e.g., a package substrate, an interposer, a circuit board, etc.), as discussed further below.

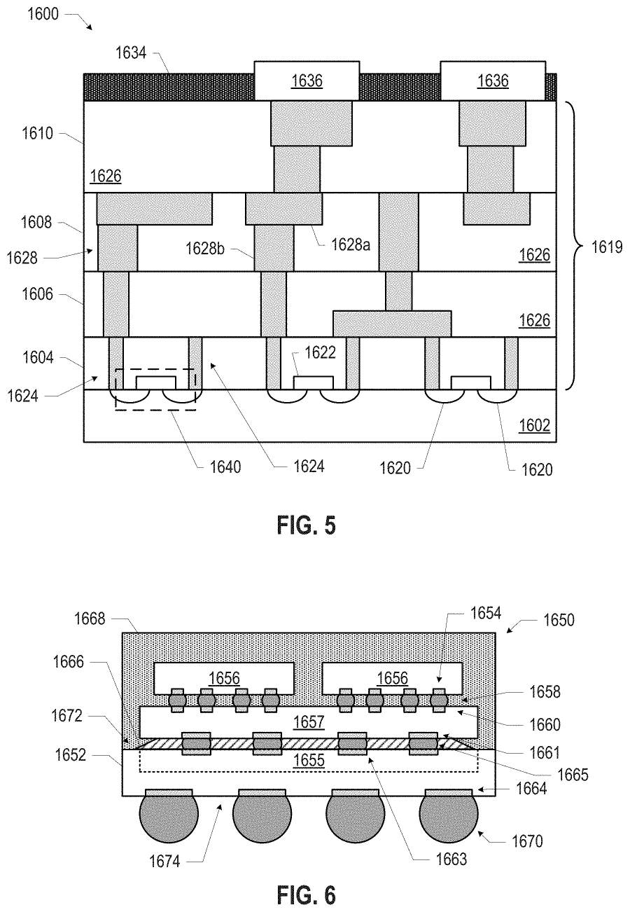

The second metal material 116 of the conductive contacts 142 may extend into a dielectric material 118 disposed below the dielectric material 106. The dielectric material 118 may be a buildup material or other suitable dielectric, and conductive structures 120 may extend through the dielectric material 118 to make electrical contact with the conductive contacts 142. The conductive structures 120 may include conductive vias and/or conductive lines (e.g., in accordance with any of the embodiments discussed below with reference to FIG. 5), and may be formed using any suitable technique (e.g., subtractive patterning, semi-additive patterning, etc.).

The dimensions of the elements of the IC package supports 100 disclosed herein may take any suitable values. For example, in some embodiments, a depth 134 of the interconnect pockets 124 may be between 200 nanometers and 500 nanometers. In some embodiments, a diameter 146 of the interconnect pockets 124 (e.g., at its narrowest point) may be between 25 microns and 250 microns. In some embodiments, a thickness 139 of the dielectric material 106 may be between 5 microns and 250 microns. In some embodiments, a thickness 138 of the first metal material 112 may be between 3 microns and 10 microns. In some embodiments, a thickness 140 of the second metal material 116 may be between 5 microns and 150 microns.

FIG. 2 illustrates an example process of manufacturing the IC package support 100 of FIG. 1. FIG. 2A illustrates an assembly 202 including a carrier 102. The carrier 102 may include any material that may be manufactured to be suitably flat (so that the structures fabricated on the carrier 102 may be as planar as achievable) and suitably stiff (so that the carrier 102 does not warp during subsequent manufacturing operations). In some embodiments, the carrier 102 may be glass, ceramic, or another suitable material.

FIG. 2B illustrates an assembly 204 subsequent to providing a layer of temporary bond film (TBF) 104 on a surface of the carrier 102 of the assembly 202 (FIG. 2A). The TBF 104 may serve to temporarily bond the carrier 102 to additional structures fabricated on the TBF 104; as discussed further below, the TBF 104 and the carrier 102 may be removed during later manufacturing stages. The TBF 104 may include an organic material that may be degraded or disrupted under a specified set of conditions, allowing the carrier 102 to be detached. In some embodiments, the organic material may be degradable upon exposure to light or a particular chemical solution, allowing the bond between the TBF 104 to be sufficiently weakened to permit detachment of the carrier 102. In some embodiments, mechanical forces may be used to detach the carrier 102 and the TBF 104. The thickness 144 of the TBF 104 may be any suitable thickness. For example, in some embodiments, the TBF 104 may have a thickness 144 between 2 microns and 100 microns.

The TBF 104 may also include metal particles, in addition to the organic material. These metal particles may allow another metal layer to be selectively electrolessly deposited on the TBF 104 (e.g., as discussed below with reference to FIGS. 2E and 3), a result not achievable using conventional TBFs. In some embodiments, the metal particles may include transition metal particles (e.g., particles of scandium, titanium, vanadium, chromium, manganese, iron, cobalt, nickel, copper, zinc, yttrium, zirconium, niobium, molybdenum, technetium, ruthenium, rhodium, palladium, silver, hafnium, tantalum, tungsten, rhenium, osmium, iridium, platinum, or gold). For example, the metal particles in the TBF 104 may include copper or gold. The metal particles included in the TBF 104 may be catalyst metals that facilitate electron transfer and reduce the activation energy necessary for the chemical reaction(s) involved in the deposition of a subsequent metal layer (e.g., electroless copper deposition). The diameter of these metal particles may have any appropriate values; for example, in some embodiments, the diameter of the metal particles in the TBF 104 may be between 10 nanometers and 100 nanometers. In some embodiments, the TBF 104 may include one or more layers of different organic materials (e.g., with one layer acting as a thermal barrier and the other designed to degrade under particular environmental conditions); in such embodiments, one or more of the layers may include metal particles.

The TBF 104 may be provided on the surface of the carrier 102 in any of a number of ways. For example, the TBF 104 may be provided as a thin film on a roll, and may be rolled and/or laminated onto the surface of the carrier 102. In other embodiments, the TBF 104 may be provided in liquid form, and may be slick coated or spray coated onto the surface of the carrier 102 and then cured.

FIG. 2C illustrates an assembly 206 subsequent to providing a dielectric material 106 on the TBF 104 of the assembly 204 (FIG. 2B). The dielectric material 106 may take the form of any of the dielectric materials disclosed herein. The TBF 104 may temporarily bond the carrier 102 and the dielectric material 106.

FIG. 2D illustrates an assembly 208 subsequent to forming openings 108 in the dielectric material 106 of the assembly 206 (FIG. 2C). The openings 108 may be formed by laser drilling or any other suitable process. As illustrated in FIG. 2D, the openings 108 may be tapered, narrowing toward the TBF 104. The diameter 146 of the openings 108 may take any of the forms discussed above. Regions of the TBF 104 may be exposed at the bottom of the openings 108.

FIG. 2E illustrates an assembly 210 subsequent to selectively electrolessly depositing a conformal layer of sacrificial metal 110 on the exposed TBF 104 at the bottoms of the openings 108 of the assembly 208 (FIG. 2D). The selective nature of the deposition may result in the sacrificial metal 110 being deposited conformally only on the TBF 104 at the bottoms of the openings 108 (and not, for example, on the top surface of the dielectric material 106). Mechanisms for the selective electroless deposition of the sacrificial metal 110 are discussed below with reference to FIG. 3. In some embodiments, the sacrificial metal 110 may include copper. The thickness 137 of the sacrificial metal 110 may take the values of any of the embodiments of the depth 134 of the interconnect pockets 124 discussed below.

FIG. 2F illustrates an assembly 212 subsequent to selectively electrolessly depositing a first metal material 112 on the sacrificial metal 110 of the assembly 210 (FIG. 2E). The first metal material 112 may take any of the forms discussed above, and the thickness 138 of the first metal material 112 may take any of the forms of the thickness 138 discussed above. In some embodiments, the first metal material 112 may be a surface finish material, as discussed above.

FIG. 2G illustrates an assembly 214 subsequent to depositing a photoresist 114 over the assembly 212 (FIG. 2F). The photoresist may be deposited to a desired thickness, and may be deposited using any suitable technique (e.g., spin coating and curing).

FIG. 2H illustrates an assembly 216 subsequent to patterning the photoresist 114 of the assembly 214 (FIG. 2G) to form openings 115 that expose the first metal material 112 in the openings 108. The openings 115 may extend beyond the shoulders of the openings 108, as shown. In some embodiments, the photoresist 114 may be lithographically patterned (e.g., selectively exposed to a light source according to a photomask and then etched).

FIG. 2I illustrates an assembly 218 subsequent to filling the openings 115 of the assembly 216 (FIG. 2H) with a second metal material 116. The second metal material 116 may take any of the forms discussed above. In some embodiments, an overburden of the second metal material 116 (and some of the photoresist 114) may be polished (e.g., using a chemical mechanical planarization technique) may be removed to planarize the top surface of the assembly 218. In some embodiments, the second metal material 116 may be deposited using an electrolytic deposition technique.

FIG. 2J illustrates an assembly 220 subsequent to removing the photoresist 114 from the assembly 218 (FIG. 2I). Any suitable etch technique may be used to remove the photoresist 114, for example.

FIG. 2K illustrates an assembly 222 subsequent to forming a dielectric material 118 and conductive structures 120 through the dielectric material 118 on the assembly 220 (FIG. 2J). The dielectric material 118 and the conductive structures 120 may take any of the forms disclosed herein, and may be formed using any suitable fabrication techniques (e.g., semi-additive processing, subtractive processing, etc.).

FIG. 2L illustrates an assembly 224 subsequent to detaching the carrier 102 and removing the TBF 104 from the assembly 222 (FIG. 2K), and “flipping” the result. The TBF 104 and the carrier 102 may be removed using any suitable technique (e.g., exposing the TBF 104 to light or a chemical solution to degrade its bonding ability, or mechanically separating the TBF 104 and the carrier 102 from the rest of the assembly 222). Upon removal of the TBF 104 and the carrier 102, the sacrificial metal 110 may be exposed.

FIG. 2M illustrates an assembly 226 subsequent to removing the sacrificial metal 110 from the assembly 224 (FIG. 2L). The sacrificial metal 110 may be removed using an etch process, for example, with the first metal material 112 acting as an etch stop. The resulting pockets in the assembly 226 may serve as the interconnect pockets 124, and the first metal material 112 and second metal material 116 may provide the conductive contacts 142.

FIG. 2N illustrates an assembly 228 subsequent to forming interconnects 122 (e.g., solder interconnects) at least partially in the interconnect pockets 124 of the assembly 226 (FIG. 2M). As discussed above, the interconnects 122 may make electrical contact with the conductive contacts 142 (and the conductive structures 120), and may be used to electrically connect the assembly 228 with other components (not shown). The assembly 228 may take the form of the IC package support 100.

As noted above, the TBFs 104 disclosed herein may enable a selective electroless metal deposition process onto the TBF 104 (e.g., of the sacrificial metal 110). This deposition process may occur in liquid phase. The metal particles included in a TBF 104 may serve as the nucleation sites for deposition of the additional metal, or may reduce another metal to allow that other metal to provide the nucleation sites. FIGS. 3A-3D illustrate an example mechanism by which a metal-impregnated TBF 104 may enable electroless deposition of a target metal film 136 onto the TBF 104. This target metal may be copper or another suitable metal.

FIG. 3A illustrates an assembly 230 including a TBF 104 having metal particles 128 distributed through an organic material 126. The organic material 126 may take any of the forms disclosed herein (e.g., single-layer or multi-layer, etc.). FIG. 3B illustrates an assembly 232 in which an electroless plating solution including target metal particles 130 (e.g., chelated copper) is provided on the surface of the TBF 104 of the assembly 230 (FIG. 3A). The electroless plating solution may also include stabilizing organics, an alkaline pH adjustor, and a reducing agent (e.g., formaldehyde). FIG. 3C illustrates an assembly 234 in which initial plating 132 of the target metal particles 130 occurs on the exposed metal particles 128 of the assembly 232 (FIG. 3B), with the exposed metal particles 128 facilitating the reduction-oxidation reaction between the target metal particles 128 and the reducing agent and thereby acting as catalysts for the plating. FIG. 3D illustrates an assembly 236 in which three-dimensional plating between the exposed metal particles 128 of the assembly 234 (FIG. 3C) occurs, resulting in a conformal target metal film 136 (which may be, for example, the sacrificial metal 110). This process may continue in an autocatalytic fashion as more freshly reduced target metal (e.g., copper) may be terminated when the conformal target metal film 136 reaches a desired thickness. The solution temperature, the deposition time, the chemical concentrations, and the identities of the organic additives (among other variables) may affect the deposition speed, thickness of the target metal film 136, and/or the stress in the target metal film 136, as known in the art.

The IC package supports 100 disclosed herein may be included in any suitable electronic component. FIGS. 4-8 illustrate various examples of apparatuses that may include any of the IC package supports 100 disclosed herein, or may be included in an IC package that also includes any of the IC package supports 100 disclosed herein.

FIG. 4 is a top view of a wafer 1500 and dies 1502 that may be included in an IC package including one or more IC package supports 100 (e.g., as discussed below with reference to FIG. 6) in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more transistors (e.g., some of the transistors 1640 of FIG. 5, discussed below) and/or supporting circuitry to route electrical signals to the transistors, as well as any other IC components. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 8) or other logic that is configured to store information in the memory devices or execute instructions stored in the memory array.

FIG. 5 is a side, cross-sectional view of an IC device 1600 that may be included in an IC package including one or more IC package supports 100 (e.g., as discussed below with reference to FIG. 6), in accordance with any of the embodiments disclosed herein. The IC device 1600 may be formed on a substrate 1602 (e.g., the wafer 1500 of FIG. 4) and may be included in a die (e.g., the die 1502 of FIG. 4). The substrate 1602 may be a semiconductor substrate composed of semiconductor material systems including, for example, n-type or p-type materials systems (or a combination of both). The substrate 1602 may include, for example, a crystalline substrate formed using a bulk silicon or a silicon-on-insulator (SOI) substructure. In some embodiments, the substrate 1602 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the substrate 1602. Although a few examples of materials from which the substrate 1602 may be formed are described here, any material that may serve as a foundation for an IC device 1600 may be used. The substrate 1602 may be part of a singulated die (e.g., the dies 1502 of FIG. 4) or a wafer (e.g., the wafer 1500 of FIG. 4).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 5 and may include a wide variety of other types and configurations such as, for example, planar transistors, non-planar transistors, or a combination of both. Planar transistors may include bipolar junction transistors (BJT), heterojunction bipolar transistors (HBT), or high-electron-mobility transistors (HEMT). Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion-implantation process. In the latter process, the substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., the transistors 1640) of the device layer 1604 through one or more metallization layers disposed on the device layer 1604 (illustrated in FIG. 5 as metallization layers 1606-1610). For example, electrically conductive features of the device layer 1604 (e.g., the gate 1622 and the S/D contacts 1624) may be electrically coupled with the conductive structures 1628 of the metallization layers 1606-1610. The one or more metallization layers 1606-1610 may form a metallization stack (also referred to as an “ILD stack”) 1619 of the IC device 1600.

The conductive structures 1628 may be arranged within the metallization layers 1606-1610 to route electrical signals according to a wide variety of designs (in particular, the arrangement is not limited to the particular configuration of conductive structures 1628 depicted in FIG. 5). Although a particular number of metallization layers 1606-1610 is depicted in FIG. 5, embodiments of the present disclosure include IC devices having more or fewer metallization layers than depicted.

In some embodiments, the conductive structures 1628 may include lines 1628a and/or vias 1628b filled with an electrically conductive material such as a metal. The lines 1628a may be arranged to route electrical signals in a direction of a plane that is substantially parallel with a surface of the substrate 1602 upon which the device layer 1604 is formed. For example, the lines 1628a may route electrical signals in a direction in and out of the page from the perspective of FIG. 5. The vias 1628b may be arranged to route electrical signals in a direction of a plane that is substantially perpendicular to the surface of the substrate 1602 upon which the device layer 1604 is formed. In some embodiments, the vias 1628b may electrically couple lines 1628a of different metallization layers 1606-1610 together.

The metallization layers 1606-1610 may include a dielectric material 1626 disposed between the conductive structures 1628, as shown in FIG. 5. In some embodiments, the dielectric material 1626 disposed between the conductive structures 1628 in different ones of the metallization layers 1606-1610 may have different compositions; in other embodiments, the composition of the dielectric material 1626 between different metallization layers 1606-1610 may be the same.

A first metallization layer 1606 may be formed above the device layer 1604. In some embodiments, the first metallization layer 1606 may include lines 1628a and/or vias 1628b, as shown. The lines 1628a of the first metallization layer 1606 may be coupled with contacts (e.g., the S/D contacts 1624) of the device layer 1604.

A second metallization layer 1608 may be formed above the first metallization layer 1606. In some embodiments, the second metallization layer 1608 may include vias 1628b to couple the lines 1628a of the second metallization layer 1608 with the lines 1628a of the first metallization layer 1606. Although the lines 1628a and the vias 1628b are structurally delineated with a line within each metallization layer (e.g., within the second metallization layer 1608) for the sake of clarity, the lines 1628a and the vias 1628b may be structurally and/or materially contiguous (e.g., simultaneously filled during a dual-damascene process) in some embodiments.

A third metallization layer 1610 (and additional metallization layers, as desired) may be formed in succession on the second metallization layer 1608 according to similar techniques and configurations described in connection with the second metallization layer 1608 or the first metallization layer 1606. In some embodiments, the metallization layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the metallization layers 1606-1610. In FIG. 5, the conductive contacts 1636 are illustrated as taking the form of bond pads. The conductive contacts 1636 may be electrically coupled with the conductive structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the metallization layers 1606-1610; for example, the conductive contacts 1636 may include other analogous features (e.g., posts) that route the electrical signals to external components.

FIG. 6 is a side, cross-sectional view of an example IC package 1650 that may include one or more IC package supports 100. For example, as discussed further below, the package substrate 1652 or the interposer 1657 of the IC package 1650 may include one or more interconnect pockets 124 in accordance with any of the embodiments disclosed herein. In some embodiments, the IC package 1650 may be a system-in-package (SiP).

The package substrate 1652 may be formed of a dielectric material (e.g., a ceramic, a buildup film, an epoxy film having filler particles therein, etc.), and may have conductive pathways (not shown) extending through the dielectric material between the face 1672 and the face 1674, or between different locations on the face 1672, and/or between different locations on the face 1674. These conductive pathways may take the form of any of the conductive structures 1628 discussed above with reference to FIG. 5. When the package substrate 1652 is an IC package support 100, these conductive pathways may include the conductive structures 120 discussed above with reference to FIG. 1.

The package substrate 1652 may include conductive contacts 1663 that are coupled to conductive pathways through the package substrate 1652, allowing circuitry within the dies 1656 and/or the interposer 1657 to electrically couple to various ones of the conductive contacts 1664 (or to other devices included in the package substrate 1652, not shown). In some embodiments, the conductive contacts 1663 may take the form of any of the embodiments of the conductive contacts 142 disclosed herein (e.g., the conductive contacts 1663 may include metal materials 112 and 116, and may be recessed behind an interconnect pocket 124). In such embodiments, the interconnect pockets 124 associated with the conductive contacts 1663 may be first-level interconnect pockets (e.g., as discussed below with reference to the first-level interconnects 1665). In some embodiments, the conductive contacts 1664 may take the form of any of the embodiments of the conductive contacts 142 disclosed herein (e.g., the conductive contacts 1663 may include metal materials 112 and 116, and may be recessed behind an interconnect pocket 124). In such embodiments, the interconnect pockets 124 associated with the conductive contacts 1664 may be second-level interconnect pockets (e.g., as discussed below with reference to the second-level interconnects 1670).

In some embodiments, the package substrate 1652 may include one or more embedded bridges 1655 (represented with dotted lines in FIG. 6) to couple the interposer 1657 (or the dies 1656 directly when no interposer 1657 is used) to the package substrate 1652. Such embedded bridges 1655 may have a higher routing density than achievable by the dielectric material in which they are embedded. In some embodiments, the embedded bridges 1655 may be silicon bridges.

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 6 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. In some embodiments, the conductive contacts 1661 may take the form of any of the embodiments of the conductive contacts 142 disclosed herein (e.g., the conductive contacts 1661 may include metal materials 112 and 116, and may be recessed behind an interconnect pocket 124). In such embodiments, the interconnect pockets 124 associated with the conductive contacts 1661 may be first-level interconnect pockets 124 for the first-level interconnects 1665.

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). When the interposer 1657 is an IC package support 100, these conductive pathways may include the conductive structures 120 discussed above with reference to FIG. 1. In some embodiments, the conductive contacts 1660 may take the form of any of the embodiments of the conductive contacts 142 disclosed herein (e.g., the conductive contacts 1660 may include metal materials 112 and 116, and may be recessed behind an interconnect pocket 124). In such embodiments, the interconnect pockets 124 associated with the conductive contacts 1660 may be first-level interconnect pockets 124 for the first-level interconnects 1658. The first-level interconnects 1658 illustrated in FIG. 6 are solder bumps, but any suitable first-level interconnects 1658 may be used.

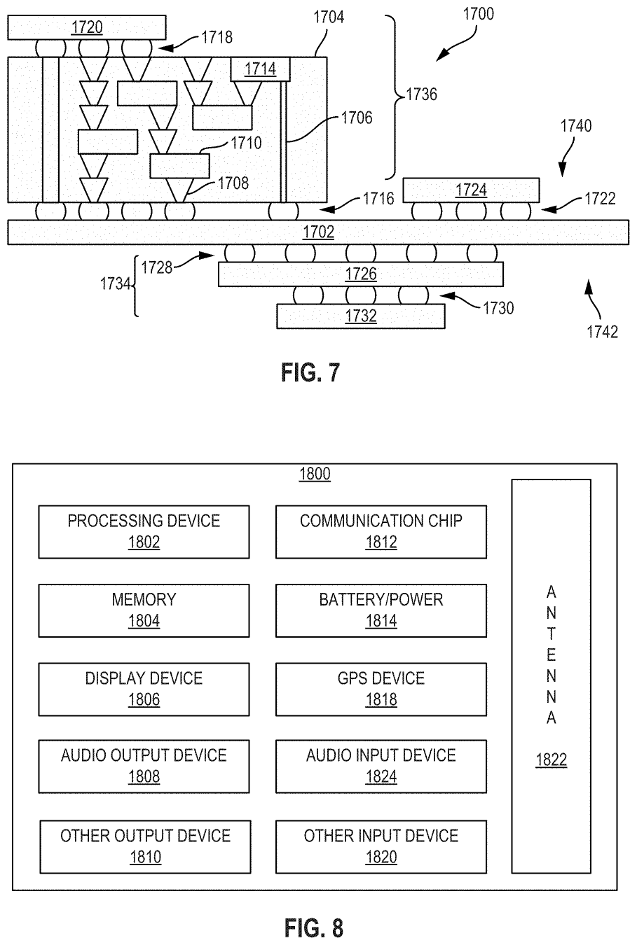

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 6 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 7.

The dies 1656 may take the form of any of the embodiments of the die 1502 discussed herein (e.g., may include any of the embodiments of the IC device 1600). In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., a central processing unit (CPU) or a graphics processing unit (GPU)), and one or more of the dies 1656 may be memory dies (e.g., high bandwidth memory (HBM)).

Although the IC package 1650 illustrated in FIG. 6 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 6, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 7 is a side, cross-sectional view of an IC device assembly 1700 that may include one or more IC packages including one or more IC package supports 100, in accordance with any of the embodiments disclosed herein. The IC device assembly 1700 includes a number of components disposed on a circuit board 1702 (which may be, for example, a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 6 (e.g., may include one or more IC package supports 100).

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 7 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 7), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 7, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 4), an IC device (e.g., the IC device 1600 of FIG. 5), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 7, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal interconnects 1708 and vias 1710, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art. In some embodiments, the package interposer 1704 may include one or more interconnect pockets 124.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 7 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 8 is a block diagram of an example electrical device 1800 that may include one or more IC package supports 100, in accordance with any of the embodiments disclosed herein. For example, any suitable ones of the components of the electrical device 1800 may include one or more of the IC device assemblies 1700, IC packages 1650, IC devices 1600, or dies 1502 disclosed herein. A number of components are illustrated in FIG. 8 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 8, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), CPUs, GPUs, cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 is an integrated circuit (IC) package support, including: an interconnect pocket having sidewalls provided by a dielectric material; and a conductive contact at a bottom of the interconnect pocket, wherein the conductive contact includes a first metal material and a second metal material, the first metal material provides a bottom surface of the interconnect pocket and is in contact with the dielectric material, the second metal material has a different composition than the first metal material, and the second metal material is in contact with the dielectric material.

Example 2 includes the subject matter of Example 1, and further specifies that the first metal material includes a noble metal.

Example 3 includes the subject matter of Example 1, and further specifies that the first metal material includes nickel, palladium, or gold.

Example 4 includes the subject matter of any of Examples 1-3, and further specifies that the first metal material has a thickness between 3 microns and 10 microns.

Example 5 includes the subject matter of any of Examples 1-4, and further specifies that the second metal material includes copper.

Example 6 includes the subject matter of any of Examples 1-5, and further specifies that the interconnect pocket has a depth between 200 nanometers and 500 nanometers.

Example 7 includes the subject matter of any of Examples 1-6, and further specifies that the interconnect pocket has a tapered shape that widens toward the bottom surface.

Example 8 includes the subject matter of any of Examples 1-7, and further specifies that the dielectric material includes a buildup material.

Example 9 includes the subject matter of any of Examples 1-8, and further specifies that the interconnect pocket is part of an opening in the dielectric material.

Example 10 includes the subject matter of Example 9, and further specifies that the second metal material extends laterally beyond the opening.

Example 11 includes the subject matter of any of Examples 9-10, and further specifies that the second metal material extends beyond the opening along an axis of the opening.

Example 12 includes the subject matter of any of Examples 1-11, and further includes: one or more lines or vias conductively coupled to the conductive contact.

Example 13 includes the subject matter of any of Examples 1-12, and further includes: solder at least partially disposed in the interconnect pocket.

Example 14 includes the subject matter of any of Examples 1-13, and further specifies that the IC package support is an interposer.

Example 15 includes the subject matter of any of Examples 1-13, and further specifies that the IC package support is a package substrate.

Example 16 includes the subject matter of any of Examples 1-13, and further specifies that the interconnect pocket is a first-level interconnect pocket.

Example 17 includes the subject matter of any of Examples 1-13, and further specifies that the interconnect pocket is a second-level interconnect pocket.

Example 18 is a temporary bond film (TBF) material, including: an organic material; and metal particles in the organic material.

Example 19 includes the subject matter of Example 18, and further specifies that the organic material includes two or more layers of different organic materials.

Example 20 includes the subject matter of any of Examples 18-19, and further specifies that the metal particles have a diameter between 10 nanometers and 100 nanometers.

Example 21 includes the subject matter of any of Examples 18-20, and further specifies that the metal particles include a transition metal.

Example 22 includes the subject matter of any of Examples 18-21, and further specifies that the TBF material is a film having a thickness between 2 microns and 100 microns.

Example 23 includes the subject matter of any of Examples 18-22, and further specifies that the TBF material is a roll of film.

Example 24 includes the subject matter of any of Examples 18-23, and further specifies that the TBF material is a fluid.

Example 25 is a method of forming an integrated circuit (IC) package support, including: providing a temporary bond film (TBF) on a first dielectric material; providing a second dielectric material on the TBF; forming openings in the second dielectric material to expose regions of the TBF; and performing selective electroless deposition of a metal material such that the metal material selectively deposits on the exposed TBF.

Example 26 includes the subject matter of Example 25, and further specifies that the TBF includes metal particles.

Example 27 includes the subject matter of Example 26, and further specifies that the TBF includes transition metal particles.

Example 28 includes the subject matter of any of Examples 25-27, and further specifies that the metal material includes copper.

Example 29 includes the subject matter of any of Examples 25-28, and further specifies that the metal material is a first metal material, and the method further includes: after performing selective electroless deposition of the first metal material, performing selective electroless deposition of a second metal material on the first metal material in the openings, wherein the second metal material has a different composition than the first metal material.

Example 30 includes the subject matter of Example 29, and further specifies that the second metal material includes nickel, palladium, or gold.

Example 31 includes the subject matter of any of Examples 29-30, and further includes: forming patterned portions of a third metal material at least partially on the second metal material and at least partially in the openings.

Example 32 includes the subject matter of Example 31, and further specifies that forming the patterned portions of the third metal material includes performing electrolytic deposition of the third metal material.

Example 33 includes the subject matter of any of Examples 31-32, and further specifies that the third metal material includes copper.

Example 34 includes the subject matter of any of Examples 31-33, and further includes: removing the TBF and the first dielectric material; and etching the first metal material to form interconnect pockets in the openings.

Example 35 includes the subject matter of any of Examples 31-34, and further specifies that providing the TBF includes laminating the TBF.

Example 36 includes the subject matter of any of Examples 31-34, and further specifies that providing the TBF includes slick coating the TBF or spray coating the TBF.

Example 37 is a computing device, including: an integrated circuit (IC) package including an interconnect pocket around a conductive contact, wherein a first metal material of the conductive contact provides a bottom of the interconnect pocket, and a second metal material of the conductive contact is spaced apart from the interconnect pocket by the first metal material; and a circuit board, wherein the IC package is coupled to the circuit board.

Example 38 includes the subject matter of Example 37, and further specifies that the IC package includes a package substrate, and the interconnect pocket is included in the package substrate.

Example 39 includes the subject matter of Example 37, and further specifies that the IC package includes an interposer, and the interconnect pocket is included in the interposer.

Example 40 includes the subject matter of Example 37, and further includes: a first-level interconnect in the interconnect pocket.

Example 41 includes the subject matter of Example 37, and further includes: a second-level interconnect in the interconnect pocket.

Example 42 includes the subject matter of any of Examples 37-41, and further specifies that the IC package includes a central processing unit (CPU) or a graphics processing unit (GPU).

Example 43 includes the subject matter of any of Examples 37-42, and further specifies that the IC package includes high bandwidth memory (HBM).

Example 44 includes the subject matter of any of Examples 37-43, and further includes: wireless communication circuitry coupled to the circuit board.

Example 45 includes the subject matter of any of Examples 37-44, and further specifies that the circuit board is a motherboard.

Example 46 includes the subject matter of any of Examples 37-45, and further includes: a display device coupled to the circuit board.

1. An integrated circuit (IC) package support, comprising:
an interconnect pocket having sidewalls provided by a dielectric material; and
a conductive contact at a bottom of the interconnect pocket, wherein the conductive contact includes a first metal material and a second metal material, the first metal material provides a bottom surface of the interconnect pocket and is in contact with the dielectric material, the second metal material has a different composition than the first metal material, and the second metal material is in contact with the dielectric material.

2. The IC package support of claim 1, wherein the first metal material includes a noble metal.

3. The IC package support of claim 1, wherein the first metal material includes nickel, palladium, or gold.

4. The IC package support of claim 1, wherein the first metal material has a thickness between 3 microns and 10 microns.

5. The IC package support of claim 1, wherein the second metal material includes copper.

6. The IC package support of claim 1, wherein the interconnect pocket is part of an opening in the dielectric material, and the second metal material extends laterally beyond the opening.

7. The IC package support of claim 1, wherein the interconnect pocket is part of an opening in the dielectric material, and the second metal material extends beyond the opening along an axis of the opening.

8. The IC package support of claim 1, further comprising:
solder at least partially disposed in the interconnect pocket.

9. The IC package support of claim 1, wherein the IC package support is an interposer.

10. The IC package support of claim 1, wherein the IC package support is a package substrate.

11. A temporary bond film (TBF) material, comprising:
an organic material; and
metal particles in the organic material.

12. The TBF material of claim 11, wherein the organic material includes two or more layers of different organic materials.

13. The TBF material of claim 11, wherein the metal particles have a diameter between 10 nanometers and 100 nanometers.

14. The TBF material of claim 11, wherein the metal particles include a transition metal.

15. The TBF material of claim 11, wherein the TBF material is a film having a thickness between 2 microns and 100 microns.

16. The TBF material of claim 11, wherein the TBF material is a roll of film or a fluid.

17. A method of forming an integrated circuit (IC) package support, comprising:
providing a temporary bond film (TBF) on a first dielectric material;
providing a second dielectric material on the TBF;
forming openings in the second dielectric material to expose regions of the TBF; and
performing selective electroless deposition of a metal material such that the metal material selectively deposits on the exposed TBF.

18. The method of claim 17, wherein the TBF includes metal particles.

19. The method of claim 17, wherein the metal material includes copper.

20. The method of claim 17, wherein the metal material is a first metal material, and the method further includes:
after performing selective electroless deposition of the first metal material, performing selective electroless deposition of a second metal material on the first metal material in the openings, wherein the second metal material has a different composition than the first metal material.

21. A computing device, comprising:
an integrated circuit (IC) package including an interconnect pocket around a conductive contact, wherein a first metal material of the conductive contact provides a bottom of the interconnect pocket, and a second metal material of the conductive contact is spaced apart from the interconnect pocket by the first metal material; and
a circuit board, wherein the IC package is coupled to the circuit board.

22. The computing device of claim 21, further comprising:
a first-level interconnect in the interconnect pocket.

23. The computing device of claim 21, further comprising:
a second-level interconnect in the interconnect pocket.

24. The computing device of claim 21, wherein the IC package includes a central processing unit (CPU) or a graphics processing unit (GPU).

25. The computing device of claim 21, wherein the IC package includes high bandwidth memory (HBM).
